(19) United States
(12) Patent Application Publication
(10) Pub. No.: US 2024/0204031 A1
(43) Pub. Date: Jun. 20, 2024

(54) PIXEL OF IMAGE SENSOR AND IMAGE SENSOR

(71) Applicant: SAMSUNG ELECTRONICS CO., LTD., Suwon-si (KR)

(72) Inventors: Daehyung Lee, Suwon-si (KR); Kwanyoung Oh, Suwon-si (KR)

(73) Assignee: SAMSUNG ELECTRONICS CO., LTD., Suwon-si (KR)

(21) Appl. No.: 18/545,488

(22) Filed: Dec. 19, 2023

(30) Foreign Application Priority Data
Dec. 19, 2022 (KR) 10-2022-0178680

(51) Int. Cl. H01L 27/146

(52) U.S. Cl. CPC H01L 27/1464; H01L 27/14603; H01L 27/14612

(57) ABSTRACT

A pixel of an image sensor and a backside illuminated image sensor are provided. The pixel includes a semiconductor substrate including a first surface and a second surface, a photoelectric conversion region formed between the first surface and the second surface of the semiconductor substrate, a floating diffusion region formed on the first surface and spaced apart from the photoelectric conversion region in a vertical direction, and a first vertical transfer gate formed inside a recess extending from the first surface of the semiconductor substrate into the inside of the semiconductor substrate and forming a first transfer channel between the photoelectric conversion region and the floating diffusion region, wherein the first vertical transfer gate may have a structure inclined with a first angle less than 90 degrees with respect to the first surface.

### CROSS-REFERENCE TO RELATED APPLICATION

This application is based on and claims priority under 35 U.S.C. § 119 to Korean Patent Application No. 10-2022-0178680, filed on Dec. 19, 2022, in the Korean Intellectual Property Office, the disclosure of which is incorporated by reference herein in its entirety.

### BACKGROUND

### 1. Field

Embodiments of the disclosure relate to a pixel of an image sensor and an image sensor including the same, and in particular, a structure of a vertical transfer gate included in a pixel of an image sensor.

### 2. Description of Related Art

An image sensor is a semiconductor device that converts an incident light into an electrical signal, and generates image information corresponding to the incident light. Recently, with the development of the computer industry and the communication industry, demand for image sensors has been increasing in various fields, such as digital cameras, camcorders, mobile phones, security cameras, and medical micro cameras.

For example, a complementary metal-oxide semiconductor (CMOS) image sensor (CIS) using a CMOS is widely used as image sensors in mobile products or small products with limited battery capacity due to low power consumption. The CIS has a simple driving method, and may integrate analog and digital signal processing circuits into a single chip, enabling miniaturization of products.

Recently, in order to improve the light receiving efficiency and photosensitivity of a CIS, a back side illumination method for receiving incident light through the back side of a substrate has been adopted, and a vertical transfer gate (VTG) is used. The VTG increases the transfer efficiency of photo charges by shortening the separation distance between a transfer gate and a photocharge accumulator by extending the transfer gate disposed on the front side of the substrate in the depth direction of the substrate.

However, as the pixel size of the image sensor is reduced, the width of the VTG is also reduced, and thus, the effective channel length of the VTG is reduced, resulting in poor charge transfer capability.

### SUMMARY

According to an aspect of the disclosure, there is provided a pixel of an image sensor capable of improving charge transfer capability.

According to another aspect of the disclosure, there is provided a pixel of an image sensor capable of preventing transmission delay in a vertical transfer gate.

According to an aspect of the disclosure, there is provided a pixel of an image sensor, the pixel including: a semiconductor substrate including a first surface and a second surface: a photoelectric conversion region between the first surface and the second surface of the semiconductor substrate; a floating diffusion region on the first surface and spaced apart from the photoelectric conversion region in a vertical direction; and a first vertical transfer gate in a first recess extending from the first surface of the semiconductor substrate to the photoelectric conversion region, the first vertical transfer gate configured to form a first transfer channel between the photoelectric conversion region and the floating diffusion region, wherein the first vertical transfer gate has a structure inclined at a first angle of less than 90 degrees with respect to the first surface of the semiconductor substrate.

According to an aspect of the disclosure, there is provided a pixel of an image sensor, the pixel including: a semiconductor substrate including a first surface and a second surface: a photoelectric conversion region between the first surface and the second surface of the semiconductor substrate; a floating diffusion region provided in a cylindrical shape extending from the first surface of the semiconductor substrate into the semiconductor substrate; and a vertical transfer gate provided in a cylindrical shape surrounding the floating diffusion region and extending from the first surface of the semiconductor substrate to the photoelectric conversion region, the vertical transfer gate configured to form a transfer channel between the photoelectric conversion region and the floating diffusion region, wherein the vertical transfer gate and the floating diffusion region have a structure inclined at an angle less than 90 degrees with the first surface.

According to an aspect of the disclosure, there is provided a backside illuminated (BSI) image sensor including: a pixel array includes a plurality of pixels configured to generate a plurality of pixel signals based on incident light: and a signal unit configured to output image data based on the plurality of pixel signals, wherein at least one of the plurality of pixels includes: a semiconductor substrate including a first surface and a second surface: a photoelectric conversion region between the first surface and the second surface: a floating diffusion region on the first surface of the semiconductor substrate and spaced apart from the photoelectric conversion region in a vertical direction: and a first vertical transfer gate in a first recess extending from the first surface of the semiconductor substrate to the photoelectric conversion region, the first vertical transfer gate configured to form a first transfer channel between the photoelectric conversion region and the floating diffusion region, wherein the first vertical transfer gate has a structure inclined toward a maximum voltage point of the photoelectric conversion region.

### BRIEF DESCRIPTION OF THE DRAWINGS

Embodiments of the disclosure will be more clearly understood from the following detailed description taken in conjunction with the accompanying drawings in which:

FIG. 1 is a block diagram illustrating an image sensor according to an embodiment;

FIG. 2 is a circuit diagram illustrating a pixel array of the image sensor shown in FIG. 1 according to an embodiment;

FIG. 3A is a plan view of a pixel according to an embodiment;

FIG. 3B is a cross-sectional view of the pixel of FIG. 3A cut in the direction A-A;

FIG. 3C is a diagram for explaining an effect in a pixel according to an embodiment;

FIG. 4A is a plan view of a pixel according to an embodiment;

FIG. 4B is a cross-sectional view of the pixel of FIG. 4A cut in the direction B-B′;

FIG. 5A is a plan view of a pixel according to an embodiment;

FIG. 5B is a cross-sectional view of the pixel of FIG. 5A cut in the direction C-C′;

FIGS. 6 to 9 are plan views of pixels according to an embodiment; and

FIGS. 10A to 10Q are cross-sectional views illustrating a method of manufacturing pixels, according to an embodiment.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The following structural or functional descriptions of examples disclosed in the disclosure are merely intended for the purpose of describing the examples and the examples may be implemented in various forms. The examples are not meant to be limited, but it is intended that various modifications, equivalents, and alternatives are also covered within the scope of the claims.

Although terms of “first” or “second” are used to explain various components, the components are not limited to the terms. These terms should be used only to distinguish one component from another component. For example, a “first” component may be referred to as a “second” component, or similarly, and the “second” component may be referred to as the “first” component within the scope of the right according to the concept of the disclosure.

It will be understood that when a component is referred to as being “connected to” another component, the component can be directly connected or coupled to the other component or intervening components may be present.

As used herein, the singular forms “a”, “an”, and “the” are intended to include the plural forms as well, unless the context clearly indicates otherwise. It should be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof. As used herein, expressions such as “at least one of” when preceding a list of elements, modify the entire list of elements and do not modify the individual elements of the list. For example, the expression, “at least one of a, b, and c” should be understood as including only a, only b, only c, both a and b, both a and c, both b and c, or all of a, b, and c.

Unless otherwise defined, all terms including technical or scientific terms used herein have the same meaning as commonly understood by one of ordinary skill in the art to which examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, examples will be described in detail with reference to the accompanying drawings. Regarding the reference numerals assigned to the elements in the drawings, it should be noted that the same elements will be designated by the same reference numerals, and redundant descriptions thereof will be omitted.

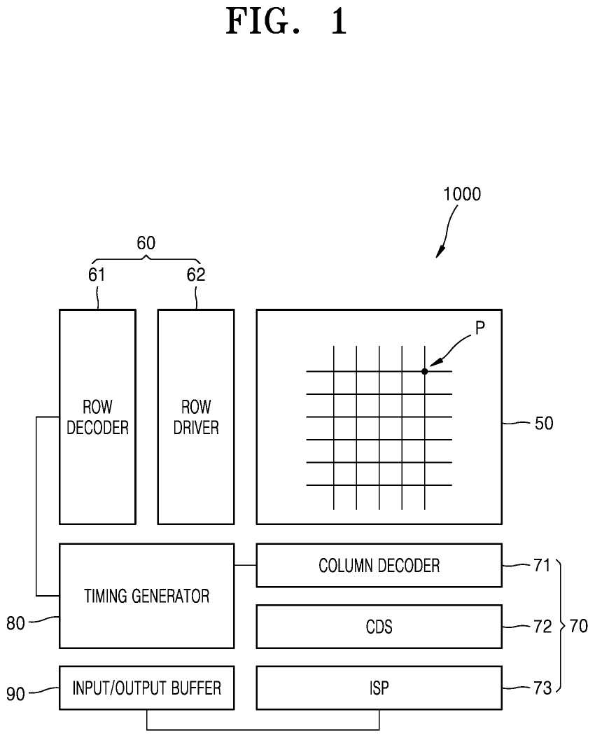

FIG. 1 is a block diagram illustrating an image sensor according to an embodiment. According to an embodiment, the image sensor shown in FIG. 1 is a complementary metal-oxide semiconductor (CMOS) image sensor. However, the disclosure is not limited thereto, and as such, according to another embodiment, the image sensor may be another type of sensor.

Referring to FIG. 1, an image sensor 1000 may include a pixel array 50, a first signal unit 60, a second signal unit 70, and a timing generator 80. The pixel array 50 includes a plurality of unit pixels P, and each of the plurality of unit pixels P converts an incident light signal into an electrical signal. The first signal unit 60 includes a row decoder 61 and a row driver 62. According to an embodiment, the first signal unit 60 applies a driving signal for each unit pixel P to the pixel array 50. The second signal unit 70 includes a column decoder 71, a correlated double sampler (CDS) 72, and an image signal processor (ISP) 73. According to an embodiment, the second signal unit 70 detects an electric signal of a unit pixel P from the pixel array 50 as a detection signal that is data for a video image. The timing generator 80 is connected to the first signal unit 60 and the second signal unit 70. The timing generator 80 is configured to selectively control the driving signal output by the first signal unit 60 and the detection signal output by the second signal unit 70. Referring to FIG. 1, the image sensor 1000 may further include an input/output buffer 90 configured to store the detection signal detected from the second signal unit 70. For example, the input/output buffer 90 stores a value corresponding to the detection signal detected from the second signal unit 70.

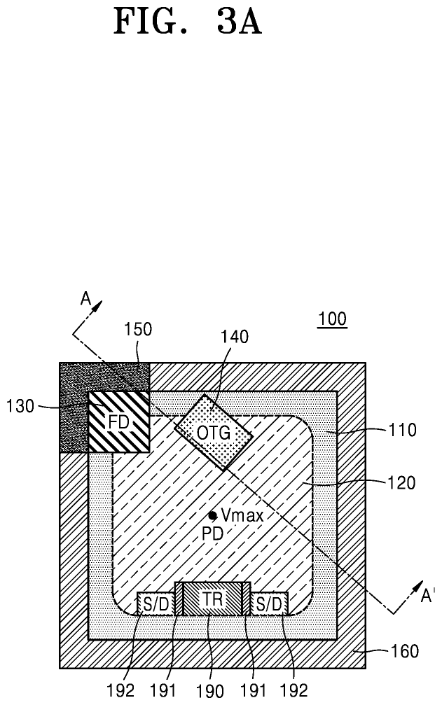

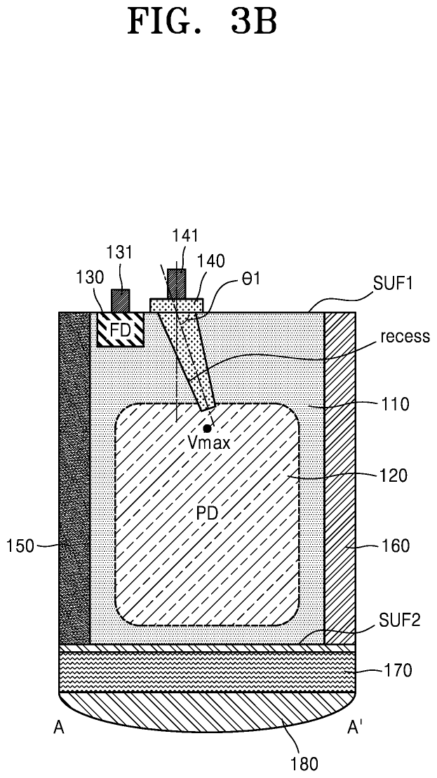

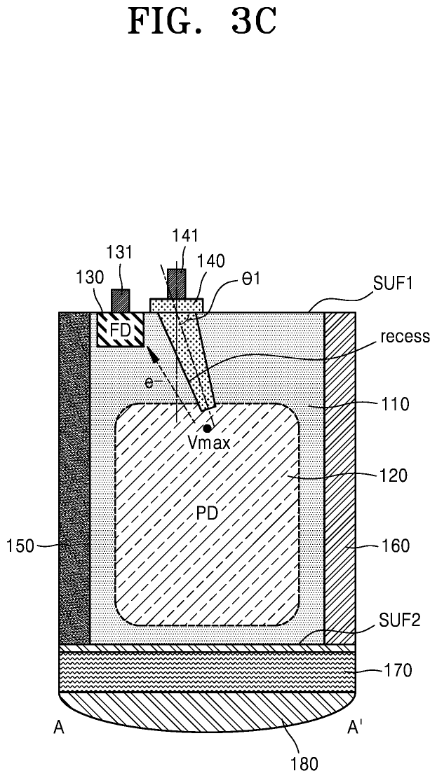

According to one example, the pixel array 50 may include a plurality of unit pixels P that are two-dimensionally arranged to have a matrix form and convert optical signals into electrical signals. According to an embodiment, one or more of the plurality of unit pixels P may include a vertical transfer gate. For example, at least some of the plurality of unit pixels P may include a vertical transfer gate. According to an embodiment, one or more of the plurality of unit pixels P may include an inclined oblique vertical transfer gate OTG (FIG. 3A). For example, at least some of the plurality of unit pixels P may include an inclined oblique vertical transfer gate OTG (FIG. 3A). A specific vertical transfer gate of the unit pixel is described below with reference to FIG. 3A or later.

The pixel array 50 may be driven by a plurality of driving signals, such as a pixel select signal, a reset signal, and a charge transfer signal, transmitted from the row driver 62. In addition, the electrical signal converted from each unit pixel may be provided to the CDS 72 through the column decoder 71.

The first signal unit 60 may apply driving signals for driving unit pixels P to the pixel array 50.

According to one example, the first signal unit 60 includes the row decoder 61 that determines a driving row of unit pixels P arranged in a matrix form and the row driver 62 that is connected to the row decoder 61 and supplies a driving signal to a driving row. Accordingly, the driving signal may be supplied to each row of the pixel array 50.

The second signal unit 70 may detect electrical signals stored in unit pixels. The second signal unit 70 may output image data by detecting electrical signals stored in a plurality of unit pixels. According to one example, the second signal unit 70 may include a column decoder 71 that determines a reading column of unit pixels P arranged in a matrix form, a CDS 72 configured to sample electrical signals from unit pixels P corresponding to detection columns, and an ISP 73 configured to process image data output from the CDS 72. The CDS 72 may double sample a specific noise level and a detection signal level corresponding to the electrical signal, and output a difference level that is a difference between the noise level and the detection signal level. The CDS 72 may further include an analog-to-digital converter (ADC) that converts an analog signal, which is an electrical signal, into a digital signal. The ADC may convert an analog signal corresponding to the difference level into a digital signal.

The ISP 73 may be implemented to process image data output from the CDS 72. For example, the ISP 73 may generate image data by performing signal processing operations, such as color interpolation, color correction, gamma correction, color space conversion, and edge correction, on received frame data. The ISP 73 may process image data to generate a subject image, and transmit the subject image to a display or store the subject image in a memory.

The timing generator 80 may be electrically connected to the first signal unit 60 and the second signal unit 70 to provide timing signals to the row decoder 61 and the column decoder 71 to control the driving row to which the driving signal is applied and the detection column in which a detection signal is detected.

The input/output buffer 90 may store the digital signal transmitted from the second signal unit 70 and sequentially transmit the digital signal to an image signal process unit (not shown) based on a decoding order in the column decoder 71.

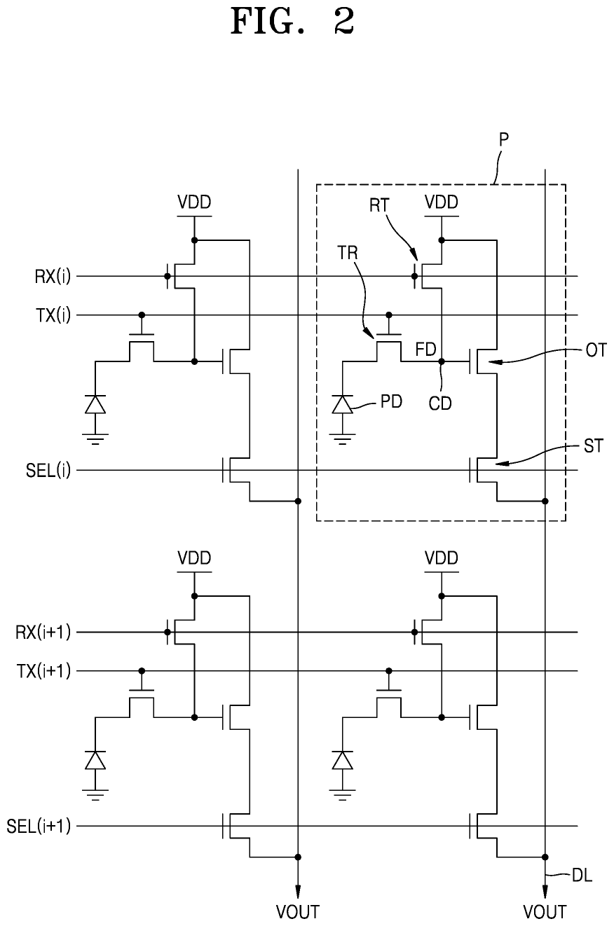

FIG. 2 is a circuit diagram illustrating a pixel array of the image sensor 1000 shown in FIG. 1 according to an embodiment. Referring to FIG. 2, the pixel array 50 may include a plurality of unit pixels P arranged in a two-dimensional matrix form.

According to an embodiment, a unit pixel P may include a photoelectric conversion device PD, a transfer transistor TR, and at least one read transistor. According to an embodiment, the at least one read transistor may be referred to as a “read transistor module” or “read transistor unit”. The photoelectric conversion device PD generates and accumulates electric charge by receiving light. The transfer transistor TR transmits photo charges generated by the photoelectric conversion device PD to a charge detector CD so as to be detected. At least one read transistor detects an electrical signal from the charge detector CD and reads video image data.

Referring to FIG. 2, the at least one read transistor may include a reset transistor RT, an output transistor OT, and a selection transistor ST. Each of the transistors may be configured as a metal oxide silicon (MOS) transistor including, for example, a metal oxide silicon.

The configuration of the at least one read transistor may be variously changed based on the configuration of the image sensor. Referring to FIG. 2, the unit pixel P is disclosed to be composed of one photoelectric conversion device PD and four transistors TR, RT, OT, and ST, but the unit pixel P may be composed of 3 transistors or 5 transistors.

Referring back to FIG. 2, the photoelectric conversion device PD may generate photo charges based on incident light and store the photo charges therein. As one embodiment, the photoelectric conversion device PD may be a photodiode, a photo transistor, a photo gate, a pinned photodiode (PPD), or a combination thereof. Charges accumulated in the photoelectric conversion device PD may be selectively transferred to the charge detector CD by the transfer transistor TR, and may be detected as an electrical signal related to a video image by an operation of the at least one read transistor including the reset transistor RT, the output transistor OT, and the selection transistor ST.

The charge detector CD may include a floating diffusion region doped with an n-type impurity in a semiconductor layer. The charge detector CD may receive, accumulate, and store the charge accumulated in the photoelectric conversion device PD. In addition, the charge detector CD may be electrically connected to the output transistor OT to control the operation of the output transistor OT.

The transfer transistor TR may selectively transfer charges stored in the photoelectric conversion device PD to the charge detector CD. The transfer transistor TR may be controlled by a charge transfer signal line TX (i) applied through a gate electrode of the MOS transistor. According to one example, the transfer transistor TR may have a structure of a vertical transfer gate. According to one example, a structure of the vertical transfer gate of the transfer transistor TR may be inclined toward a maximum voltage point included in the photoelectric conversion device PD. Through such a structure, the transfer capability of charges included in the photoelectric conversion device PD may be improved. A detailed description of this is provided below.

The reset transistor RT may be connected between a node supplying a power supply voltage VDD and a floating diffusion node FD constituting the charge detector CD to reset charges stored in the charge detector CD. For example, the reset transistor RT may be composed of one MOS transistor having a source electrode connected to the charge detector CD and a drain electrode connected to the power voltage VDD line. In this case, the reset transistor RT may be driven by a reset signal provided through a reset signal line RX (i). When the reset transistor RT is turned on by the reset signal, the power supply voltage VDD connected to the drain electrode of the reset transistor RT may be applied to the charge detector CD. Accordingly, when the reset transistor RT is enabled, the charge detector CD may be reset.

The output transistor OT may be combined with a constant current source (not shown) positioned outside the unit pixel P to constitute a source follower buffer amplifier. The output transistor OT may be connected to the diffusion node of the charge detector CD to amplify a potential change of charge stored in the charge detector CD and convert the amplified potential change of charge into an output voltage VOUT.

The selection transistor ST is connected between the source of the output transistor OT and the ground to selectively output the output voltage VOUT. The selection transistor ST may select the unit pixels P to be read in row units, and transmit an output voltage VOUT of the selected unit pixels P as an image signal along a column-direction detection line DL. For example, the selection transistor ST may be driven by a pixel selection signal provided by a selection signal line SEL (i), and when the selection transistor ST is turned on, the power supply voltage VDD connected to the drain electrode of the output transistor OT may be transferred to the drain electrode of the selection transistor ST.

The charge transfer, reset, and selection signal lines TX (i), RX (i), and SEL (i) driving the transfer transistor TR, the reset transistor RT, and the selection transistor ST may be arranged in a line in a row direction to simultaneously apply a charge transfer signal, a reset signal, and a pixel selection signal to a plurality of unit pixels P.

As described above, the unit pixel P composed of the photoelectric conversion device PD, the charge detector CD, and the at least one read transistor may be formed on a semiconductor substrate in a structure described below, and a plurality of unit pixels P may be arranged in a matrix form in the row and column directions of the pixel array 50.

FIG. 3A is a plan view of a pixel according to an embodiment. FIG. 3B is a cross-sectional view of the pixel of FIG. 3A cut in the direction A-A′.

Referring to FIGS. 3A and 3B, a pixel 100 of an image sensor according to an embodiment may include a semiconductor substrate 110, a photoelectric conversion region 120, a floating diffusion region 130, a vertical transfer gate 140, a transistor TR 190, a gate spacer 191, and a source/drain region S/D 192, formed on the semiconductor substrate 110. According to an embodiment, the pixel 100 of the image sensor may further include a color filter 170 and a micro lens 180. In the embodiments illustrated in the following drawings, the structure of the vertical transfer gate 140 included in the pixel 100 of the image sensor may refer to a structure of the gate included in the transfer transistor TR of FIG. 2. In the embodiments illustrated in the following drawings, the structure of the transistor TR 190 included in the plan view of the pixel 100 of the image sensor may refer to a structure of at least one transistor for signal output, such as the reset transistor RT, a output transistor OT, and the selection transistor ST of FIG. 2. Gate spacers 191 may be provided on both sides of the gate of the transistor TR 190. Source/drain regions 192 may be provided on both sides of the gate spacers 191 of the transistor TR 190. For example, a source region may be provided on one side (e.g., a first side) of the transistor TR 190 and a drain region may be provided on another side (e.g., a second side opposite to the first side) of the transistor TR. A gate oxide may be included at the bottom of the gate of the transistor TR 190, but because a plan view is shown in FIG. 3A, the gate oxide is omitted from the drawing. In addition, only one transistor TR 190 is illustrated, but the pixel 100 may include a plurality of transistors 190 corresponding to the reset transistor RT, a output transistor OT, and the selection transistor ST of FIG. 2.

Referring to FIG. 3B, the semiconductor substrate 110 may have a first surface SUF1 and a second surface SUF2 opposite to the first surface SUF1. In one embodiment, the image sensor including pixels may be a backside illumination (BSI)-type image sensor.

In this case, the vertical transfer gate 140 or another transistor may be formed on the first surface SUF1 (e.g., the front surface) of the semiconductor substrate 110, and incident light may reach the photoelectric conversion region through the second surface SUF2 (e.g., the rear surface) of the semiconductor substrate 110. In addition, in one embodiment, the semiconductor substrate 110 may include a semiconductor layer formed through an epitaxial process. In one embodiment, the semiconductor substrate 110 may be formed by doping impurities of a first conductivity type (e.g., p-type).

The photoelectric conversion region 120 may be formed in the semiconductor substrate 110 and generate charges (e.g., photo charges) based on the incident light. For example, electron-hole pairs may be generated based on the incident light, and the photoelectric conversion region 120 may collect these electrons or holes. For convenience of description, the photoelectric conversion region 120 is shown as a photodiode PD in FIG. 3B, but the photoelectric conversion region 120 may include a photodiode, a PPD, a photo transistor, a photo gate, or a combination thereof.

According to an embodiment illustrated in FIG. 3B the photoelectric conversion region 120 is spaced apart from the second surface SUF2 of the semiconductor substrate 110. However, the disclosure is not limited thererto, and as such, according to another embodiment, the photoelectric conversion region 120 may extend to the second surface SUF2 of the semiconductor substrate 110.

The floating diffusion region 130 is formed in the semiconductor substrate 110 and is spaced apart from the photoelectric conversion region 120. Charges generated in the photoelectric conversion region 120 may be transferred by the vertical transfer gate 140 and stored in the floating diffusion region 130. In one embodiment, the floating diffusion region 130 may be formed by doping impurities of a second conductivity type (e.g., n-type).

According to an embodiment, the vertical transfer gate 140 may be an oblique vertical transfer gate 140 formed in a recess extending from the first surface SUF1 of the semiconductor substrate 110 into the inside of the semiconductor substrate 110 towards the photoelectric conversion region 120. According to one example, the vertical transfer gate 140 may be provided in an inclined angle. According to one example, the vertical transfer gate 140 may be provided in an inclined angle with the first surface SUF1 at an angle of less than 90 degrees. According to an embodiment, the vertical transfer gate 140 may have structure that decreases in width in a direction towards the photoelectric conversion region 120. For example, a first width of the vertical transfer gate 140 at the first surface SUF1 is greater than a second width of the vertical transfer gate 140 at the photoelectric conversion region 120.

Referring to FIG. 3B, the vertical transfer gate 140 may have a structure inclined at an angle of θ1 with the first surface SUF1. According to one example, an angle θ1 between the vertical transfer gate 140 and the first surface SUF1 may be less than 90°. The vertical transfer gate 140 may form a transfer channel between the photoelectric conversion region 120 and the floating diffusion region 130 based on a transmission signal to transfer charges generated in the photoelectric conversion region 120 to the floating diffusion region 130.

Referring to FIG. 3B, the vertical transfer gate 140 may have a structure inclined toward a maximum voltage point Vmax of the photoelectric conversion region 120. According to one example, the angle θ1 formed by the vertical transfer gate 140 and the first surface SUF1 may be an angle formed by the first surface SUF1 and a straight line extending from a point where the vertical transfer gate 140 is formed on the first surface SUF1 in the direction of the maximum voltage point Vmax.

Referring to FIG. 3B, the vertical transfer gate 140 may have a structure inclined toward a point having the highest voltage in the photoelectric conversion region 120. According to one example, the maximum voltage point Vmax may mean a point at which doping concentration of impurities of the second conductivity type is highest in the photoelectric conversion region 120. In this case, the impurity of the second conductivity type may be an n-type impurity. A point in the photoelectric conversion region 120 with the highest doping concentration of the impurity of the second conductivity type may be a point with the highest electron potential.

According to an embodiment, the vertical transfer gate 140 is illustrated as being inclined toward the maximum voltage point Vmax located at the center point of the photoelectric conversion region 120. However, the disclosure is not limited thereto, and as such, according to another embodiment, the maximum voltage point Vmax may be not only the center point of the photoelectric conversion region 120 but also other positions.

Referring back to FIG. 3B, the vertical transfer gate 140 and the floating diffusion region 130 may include metal contacts 141 and 131, respectively. The vertical transfer gate 140 and the floating diffusion region 130 may receive or transmit electrical signals through the metal contacts 141 and 131 respectively connected thereto.

According to an embodiment, the image sensor may include a plurality of pixels, each having a structure of the pixel 100 illustrated in FIGS. 3A-3C. The plurality of pixels of the image sensor may further include a deep trench isolation (DTI) structure 160 formed to surround each pixel 100. The DTI structure 160 may be formed by extending from the first surface SUF1 of the semiconductor substrate 110 to a predetermined depth or completely penetrating the semiconductor substrate 110 from the first surface SUF1 to the second surface SUF2 of the semiconductor substrate 110. In addition, in another embodiment, the DTI structure 160 may be formed to a predetermined depth from the second surface SUF2 of the semiconductor substrate 110 or by completely penetrating the semiconductor substrate 110. For example, the DTI structure 160 may include any insulating material, such as silicon oxide (SiOₓ), silicon nitride (SiNₓ), or hafnium oxide (HfOₓ). As the pixel 100 is isolated from adjacent pixels by the DTI structure 160, optical and/or electrical crosstalk between the pixels 100 may be prevented.

According to one example, each pixel 100 of the image sensor may include an active region 150 instead of the DTI structure 160 surrounding each pixel 100.

The color filter 170 may be formed on the second surface SUF2 of the semiconductor substrate 110 to correspond to the photoelectric conversion region 120. The color filter 170 may be included in a color filter array arranged in a matrix form. In one embodiment, the color filter array may have a Bayer pattern including a red filter, a green filter, and a blue filter. In another embodiment, the color filter array may include a yellow filter, a magenta filter, and a cyan filter. In addition, the color filter array may additionally include a white filter. On the other hand, depending on the embodiment, an antireflection layer, at least one insulating layer, or the like may be formed between the second surface SUF2 of the semiconductor substrate 110 and the color filter 170.

The micro lens 180 may be formed to correspond to the color filter 170 and the photoelectric conversion region 120. The micro lens 180 may adjust the path of the incident light so that the incident light incident on the micro lens 180 may be focused on the photoelectric conversion region 120. In addition, the micro lens 180 may be included in a micro lens array arranged in a matrix form.

FIG. 3C is a diagram for explaining an effect in a pixel according to an embodiment.

Referring to FIG. 3C, an operation of a pixel 100 of an image sensor according to an embodiment is described as follows. When the vertical transfer gate 140 is turned on, charges generated in the photoelectric conversion region 120 may move to the floating diffusion region 130 along a charge transfer path from the photoelectric conversion region 120 to the floating diffusion region 130. That is, in the pixel 100 of the image sensor, when electrons included in the photoelectric conversion region 120 are transferred to the floating diffusion region 130 through the structure of the vertical transfer gate 140 that is inclined, the electrons may be transferred along a straight line (the arrow in FIG. 3C). Accordingly, charge transfer capability may be improved according to an embodiment.

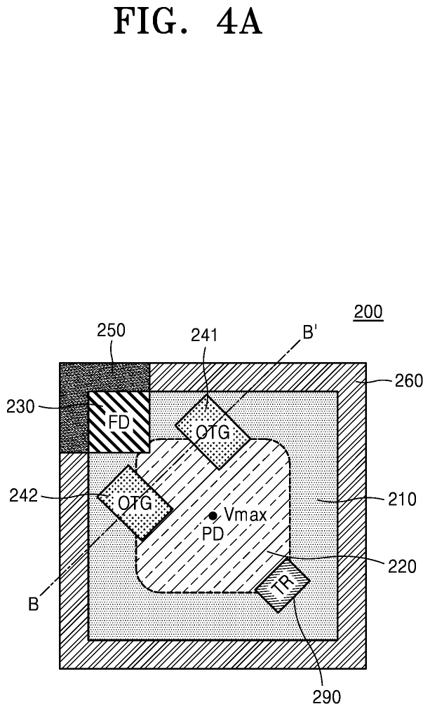

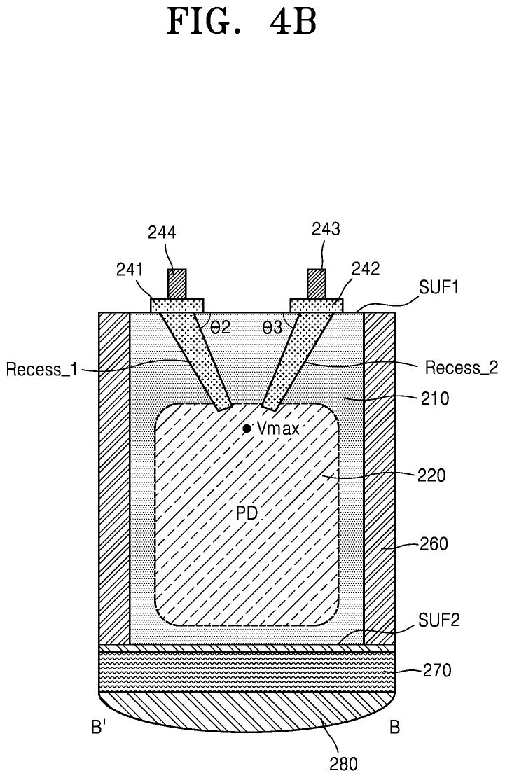

FIG. 4A is a plan view of a pixel according to an embodiment. FIG. 4B is a cross-sectional view of the pixel of FIG. 4A cut in the direction B-B′. Regarding FIGS. 4A and 4B, descriptions already given with respect to FIGS. 3A and 3B are omitted.

Referring to FIGS. 4A and 4B, a pixel 200 of the image sensor may include a semiconductor substrate 210, a photoelectric conversion region 220, a floating diffusion region 230, a first vertical transfer gate 241, a second vertical transfer gate 242, and a transistor 290. According to an embodiment, the pixel 200 of the image sensor may further include a deep trench isolation (DTI) structure 260 formed to surround the pixel 200. According to one example, the pixel 200 of the image sensor may include an active region 250.

According to one example, in the transistor 290 of FIG. 4A, a gate spacer 191 and a source/drain region 192 may be provided as shown in FIG. 3A, but the gate spacer 191 and the source/drain region 192 are omitted for description.

The first vertical transfer gate 241 and the second vertical transfer gate 242 may be provided in an inclined structure. According to one example, the first vertical transfer gate 241 and the second vertical transfer gate 242 may be provided in a structure inclined toward the maximum voltage point Vmax of the photoelectric conversion region 220. The first vertical transfer gate 241 and the second vertical transfer gate 242 may be formed in a slanted first recess (recess_1) and a slanted second recess (recess_2), respectively.

Referring to FIG. 4B, the first vertical transfer gate 241 may be provided in a structure inclined toward the left direction. Referring to FIG. 4B, the second vertical transfer gate 242 may be provided in a structure inclined toward the right direction.

Referring to FIG. 4B, the first vertical transfer gate 241 may be provided in a structure inclined by θ2 with respect to the first surface SUF1. The second vertical transfer gate 242 may be provided in a structure inclined with respect to the first surface SUF1 by θ3. According to one example, θ2 may have the same value as θ3.

According to one example, the first vertical transfer gate 241 and the second vertical transfer gate 242 may be symmetrical to each other. According to one example, the first vertical transfer gate 241 and the second vertical transfer gate 242 may have structures symmetrical to each other with respect to the maximum voltage point Vmax of the photoelectric conversion region 220. According to an embodiment, the first vertical transfer gate 241 and the second vertical transfer gate 242 may include metal contacts 244 and 243, respectively. According to an embodiment, the pixel 200 of the image sensor may further include a color filter 270 and a micro lens 280.

Referring to FIGS. 4A and 4B, the pixel 200 of the image sensor may include one photoelectric conversion region 220 and a plurality of vertical transfer gates (the first and second vertical transfer gates 241 and 242). Charge transfer capability may be further improved by including a plurality of inclined vertical transfer gates (the first and second vertical transfer gates 241 and 242).

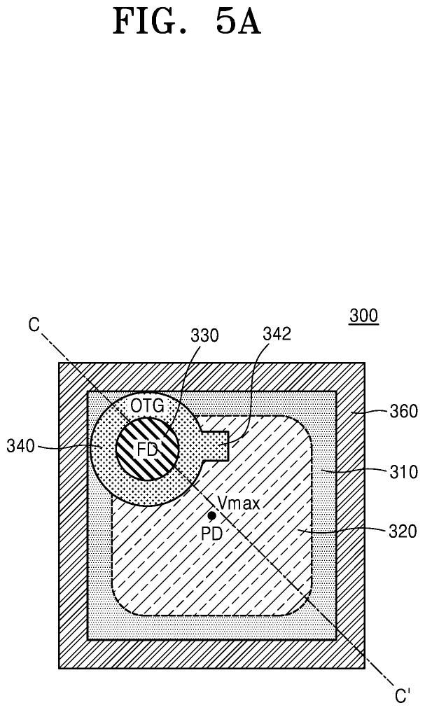

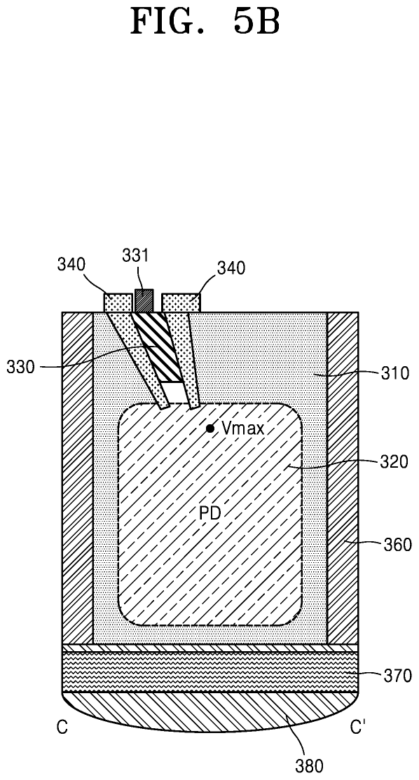

FIG. 5A is a plan view of a pixel according to an embodiment. FIG. 5B is a cross-sectional view of the pixel of FIG. 5A cut in the direction C-C′. Regarding FIGS. 5A and 5B, descriptions already given with respect to FIGS. 3A and 3B are omitted.

According to an embodiment, a pixel 300 of the image sensor of FIGS. 5A and 5B may include a semiconductor substrate 310, a photoelectric conversion region 320, a floating diffusion region 330, and a vertical transfer gate 340. According to an embodiment, the pixel 300 of the image sensor may further include a deep trench isolation (DTI) structure 360 formed to surround the pixel 300.

Referring to FIG. 5B, the floating diffusion region 330 may have a cylindrical structure. Referring to FIG. 5B, the floating diffusion region 330 may have a depth that is less than that of the vertical transfer gate 340. According to one example, the vertical transfer gate 340 may be provided in a cylindrical shape surrounding the floating diffusion region 330. Referring to FIG. 5A, the vertical transfer gate 340 may include an extension 342 for a metal contact thereon. According to an embodiment, the floating diffusion region 330 may include metal contacts 331. According to an embodiment, the pixel 300 of the image sensor may further include a color filter 370 and a micro lens 380.

Referring to FIGS. 5A and 5B, because the vertical transfer gate 340 has a cylindrical shape, the charge transfer channel may be further expanded, and the charge transfer rate may be increased through the inclined structure of the vertical transfer gate 340.

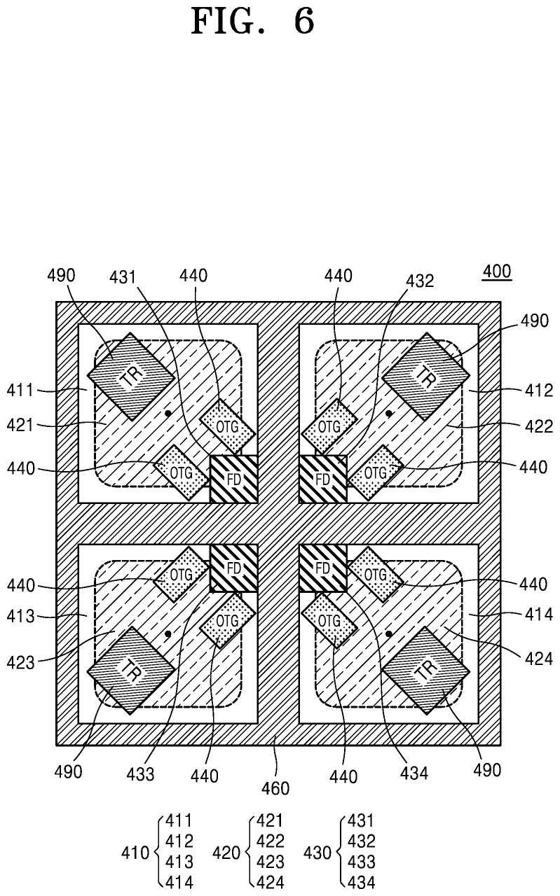

FIGS. 6 to 9 are plan views of pixels according to an embodiment.

Vertical transfer gates included in the pixels according to the embodiments of FIGS. 6 to 9 may be provided in a structure inclined toward a maximum voltage point of a photoelectric conversion region. Because the structures and characteristics of the inclined vertical transfer gates are the same as those described above, cross-sectional views are omitted, and plan views of various pixel structures to which the inclined vertical transfer gates may be applied are described below.

According to an embodiment, a pixel 400 of the image sensor of FIG. 6 may have a structure in which four pixels 200 of the image sensor of FIG. 4A are combined. Referring to FIG. 6, the pixel 400 of an image sensor having a 2*2 pixel structure symmetrical about a center is disclosed.

The pixel 400 of the image sensor of FIG. 6 includes four semiconductor substrates 410, four photoelectric conversion regions 420, four floating diffusion regions 430, eight vertical transfer gates 440, a DTI structure 460, and transistors 490. Each of the eight vertical transfer gates 440 may be provided in a structure inclined toward the maximum voltage point Vmax of the photoelectric conversion region 420 corresponding to a region including each vertical transfer gate 440. In FIG. 6, the four semiconductor substrates 410 are illustrated as semiconductor substrates 411-414, the four photoelectric conversion regions 420 are illustrated as photoelectric conversion regions 421-424, and the four floating diffusion regions 430 are illustrated as floating diffusion regions 431-434.

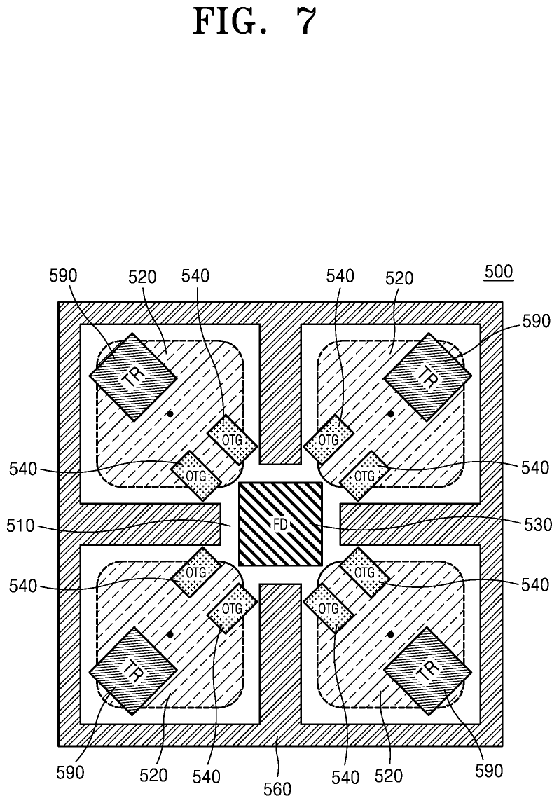

According to an embodiment, a pixel 500 of the image sensor of FIG. 7 include one semiconductor substrate 510, four photoelectric conversion regions 520, one floating diffusion region 530, eight vertical transfer gates 540, and a DTI structure 560, and transistors 590. The pixels 500 of the image sensor of FIG. 7 may have a 4PD structure in which the central portion of the DTI structure 460 is partially removed from the pixel 400 of the image sensor of FIG. 6 to share the semiconductor substrate 510. The pixels 500 of the image sensor of FIG. 7 may have a structure in which the separated floating diffusion regions 430 in FIG. 6 are combined into one floating diffusion region 530.

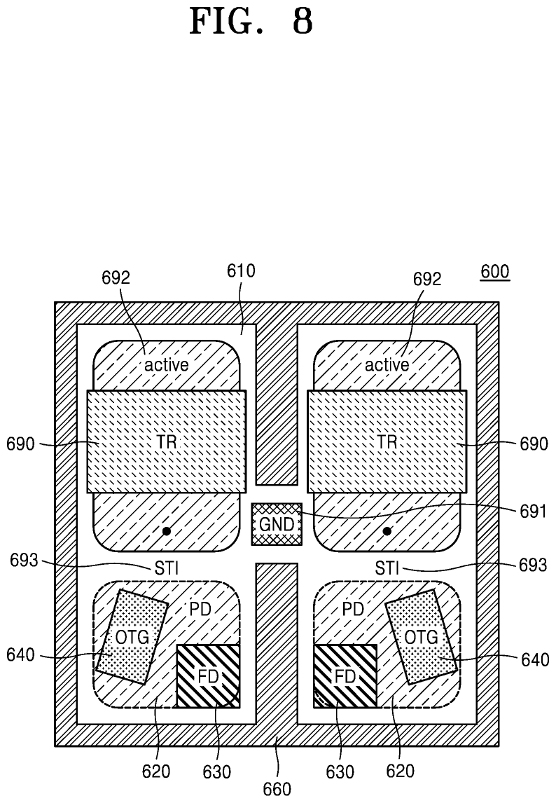

According to an embodiment, a pixel 600 of the image sensor of FIG. 8 may be a plan view illustrating a pixel structure of an image sensor including two photodiodes. The pixel 600 of the image sensor of FIG. 8 may include one semiconductor substrate 610, two photoelectric conversion regions 620, two floating diffusion regions 630, two vertical transfer gates 640, a DTI structure 660, other transistors 690, an active region 692 of the transistor 690, a shallow trench isolation (STI) region 693, and ground 691. In this case, the other transistors 690 may be any one of a selection transistor, a driving transistor, and an output transistor. The DTI structure 660 may not completely separate the two photodiodes, and the ground 691 may be disposed between the photoelectric conversion regions 620 corresponding to the two photodiodes. The active region 692 of the transistor 690 and the photoelectric conversion region 620 may be separated from each other.

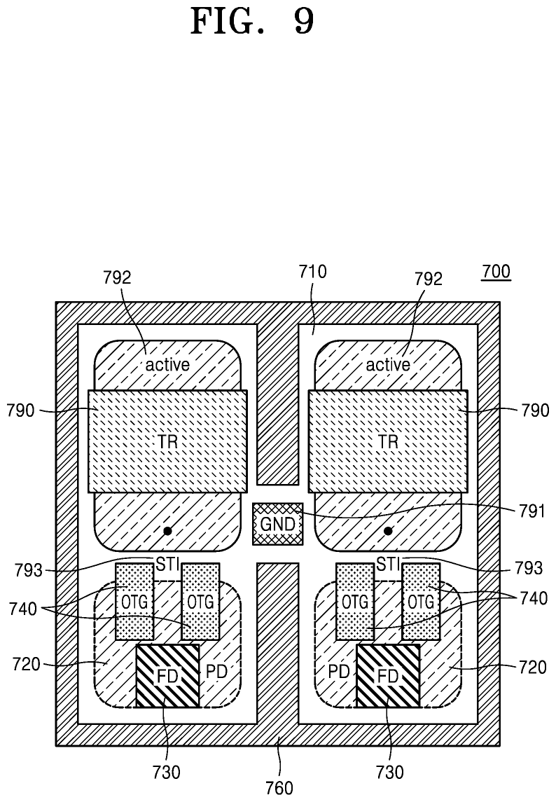

According to an embodiment, a pixel 700 of the image sensor of FIG. 9 may include one semiconductor substrate 710, two photoelectric conversion regions 720, two floating diffusion regions 730, four vertical transfer gates 740, a DTI structure 760, other transistors 790, active regions 792 of the transistors 790, STI regions 793, and ground 791. The pixel 700 of the image sensor of FIG. 9 may be an embodiment including a plurality of vertical transfer gates 740 in a region corresponding to one photoelectric conversion region 720 in the pixel 600 of the image sensor of FIG. 8. The active region 792 of the transistor 790 and the photoelectric conversion region 720 may be separated from each other.

According to an embodiment, an inclined vertical transfer gate structure may be applied to structures of various pixels including vertical transfer gates. The vertical transfer gate may be inclined toward a maximum voltage point of the photoelectric conversion region. Due to the inclination of the vertical transfer gate, a transmission path of electrons moving from the photoelectric conversion region to the floating diffusion node may be shortened, and charge transfer capability may be improved.

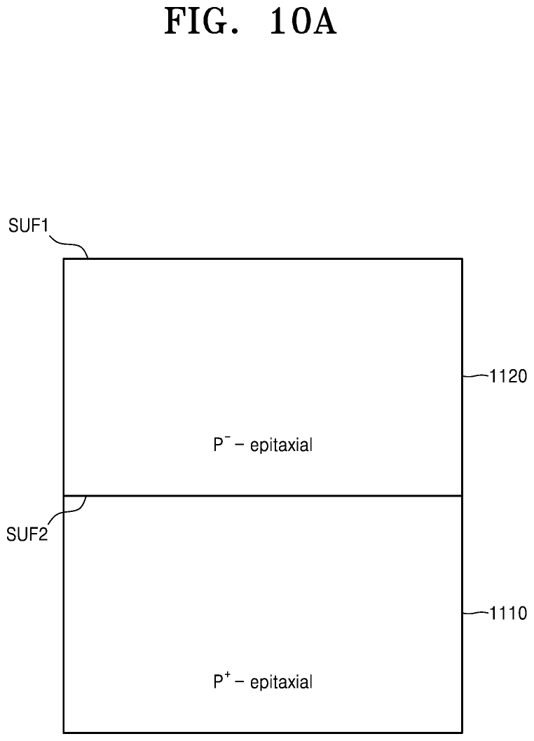

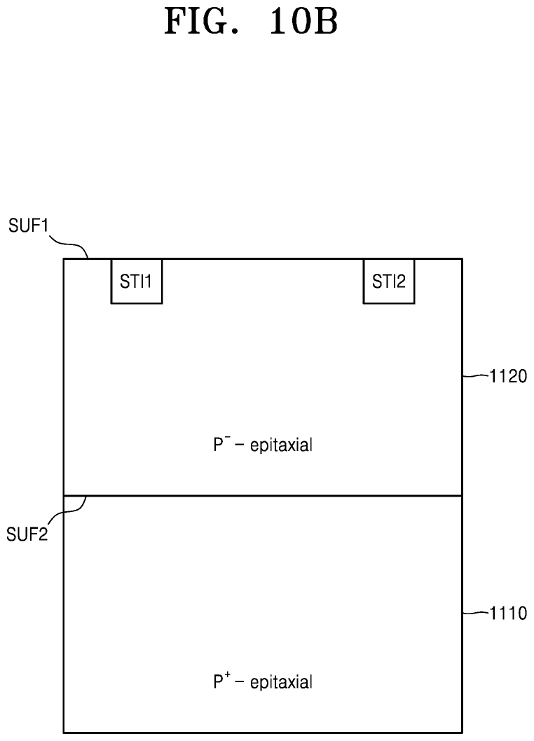

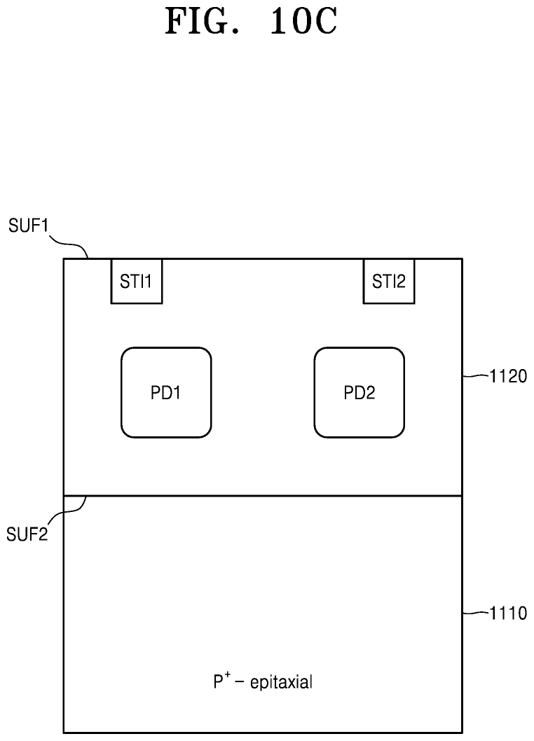

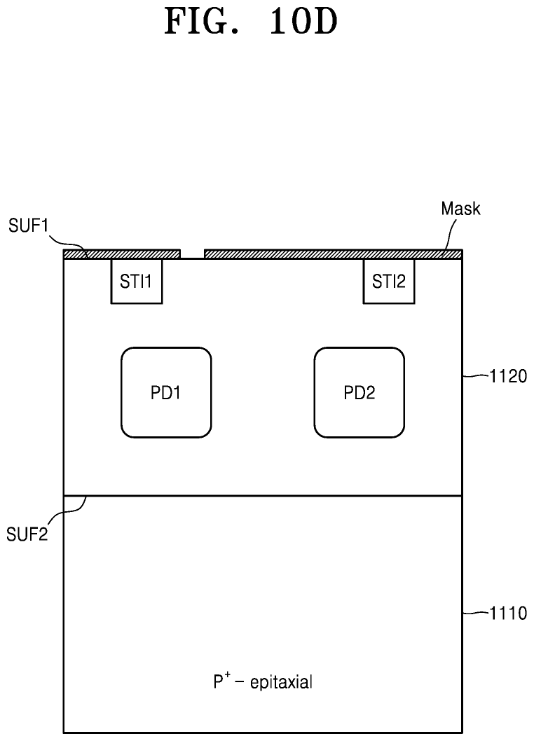

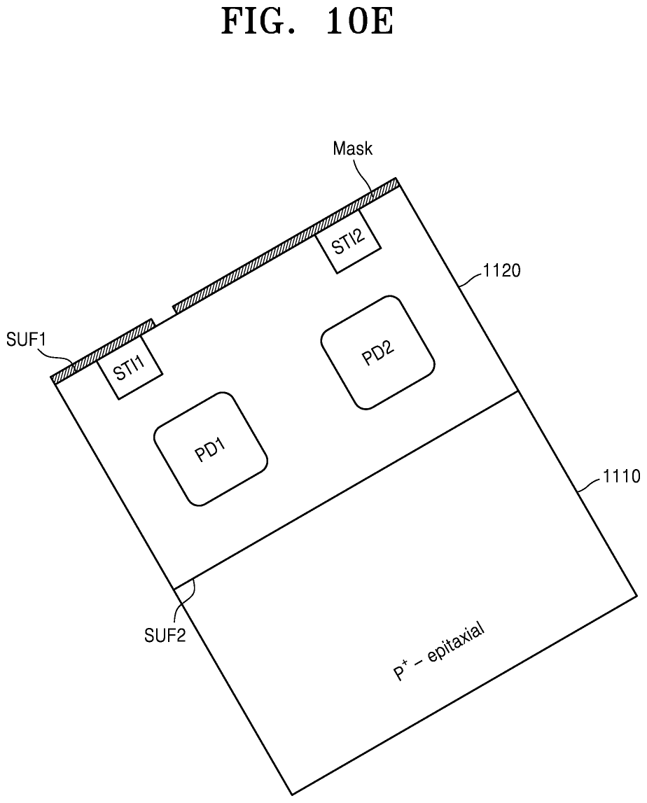

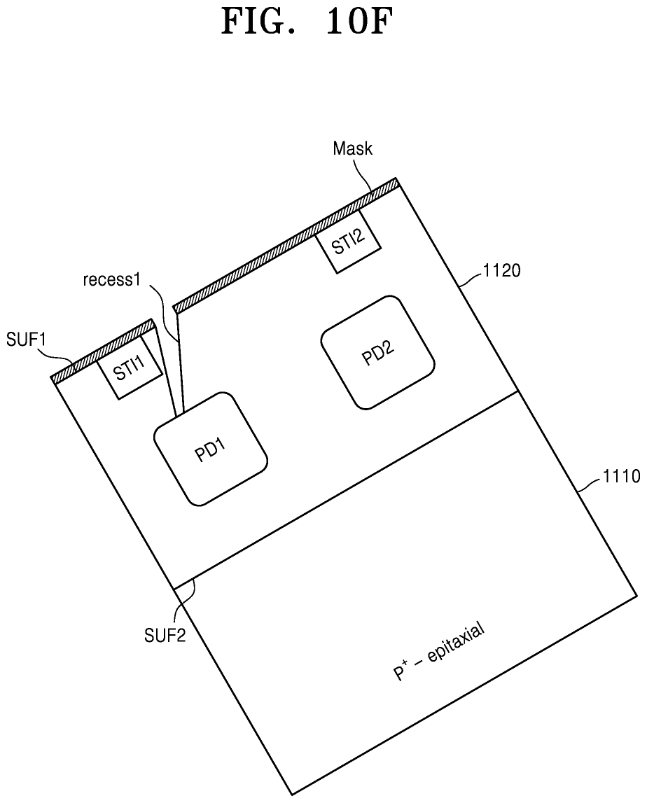

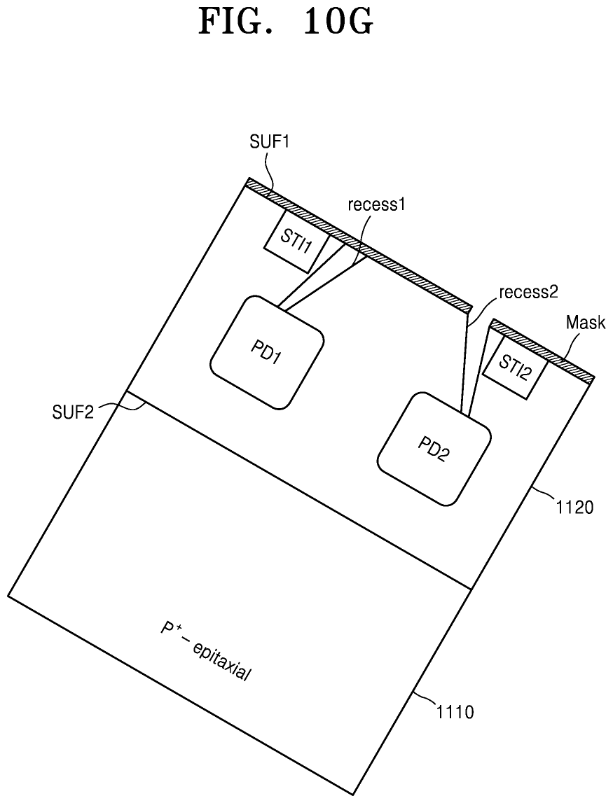

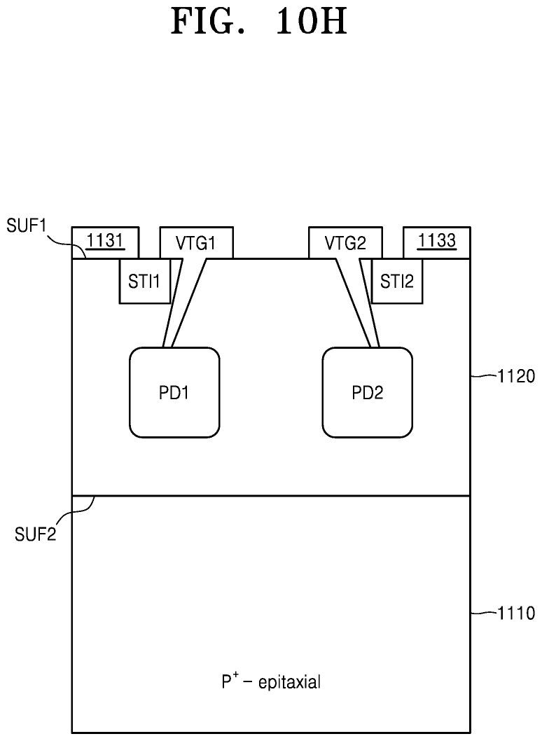

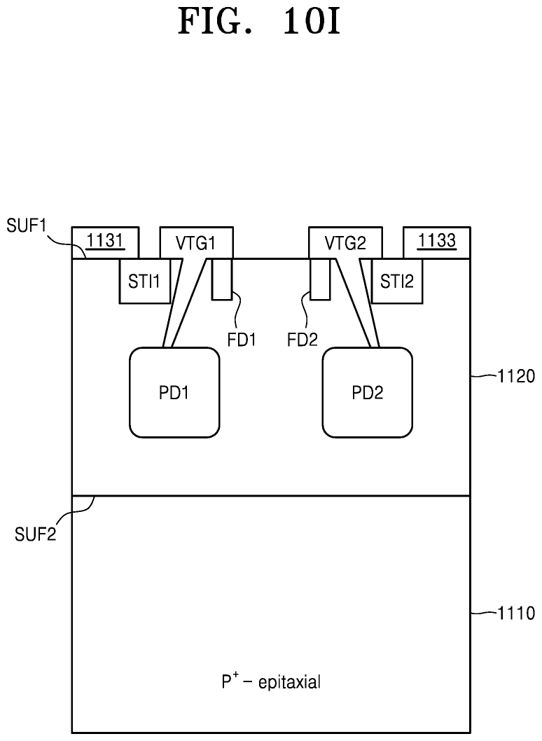

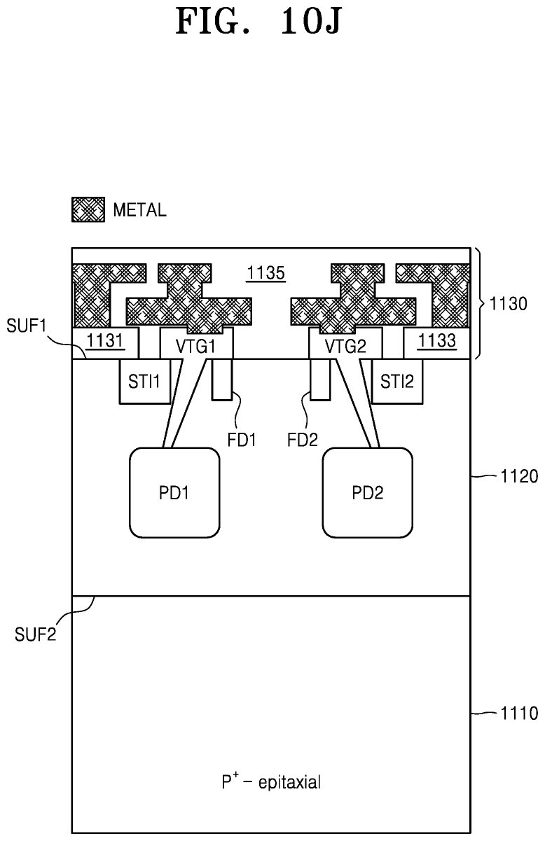

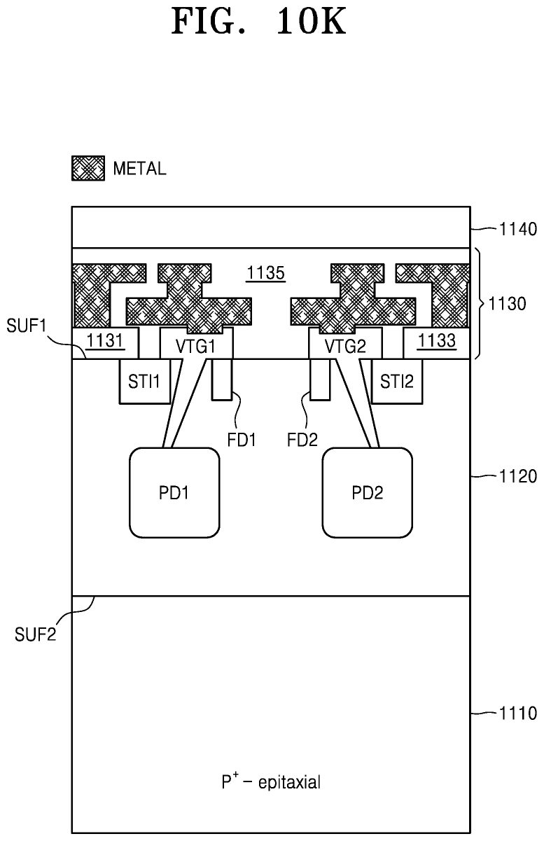

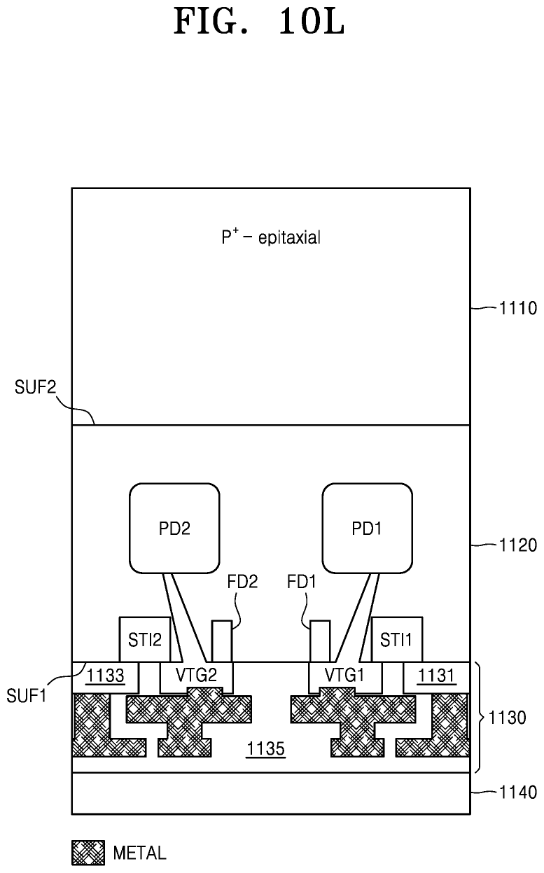

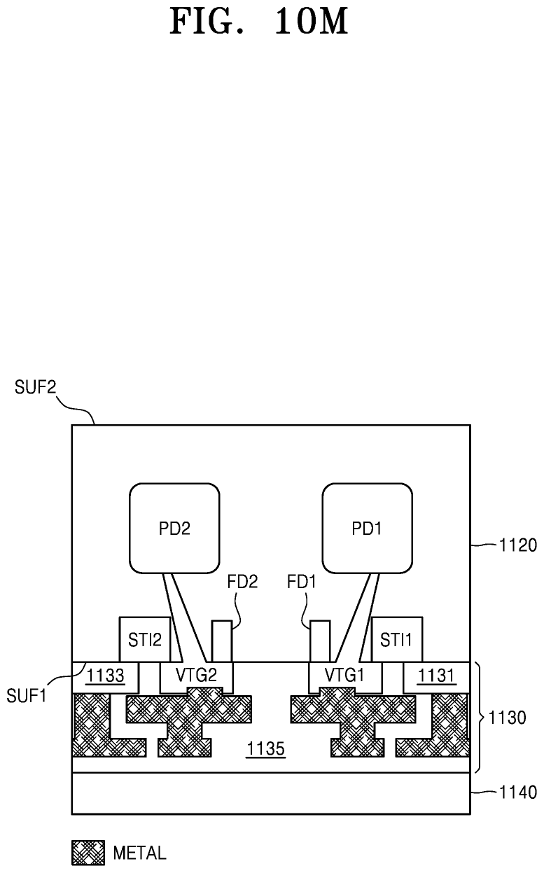

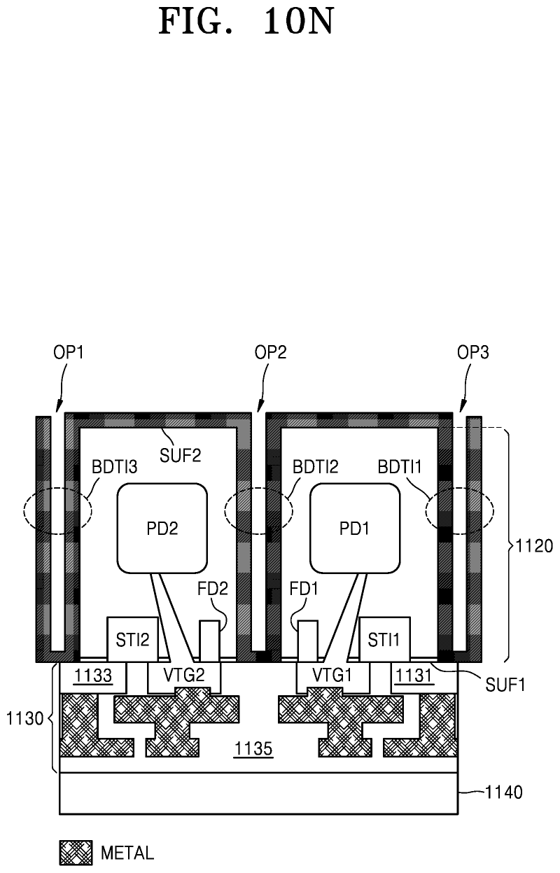

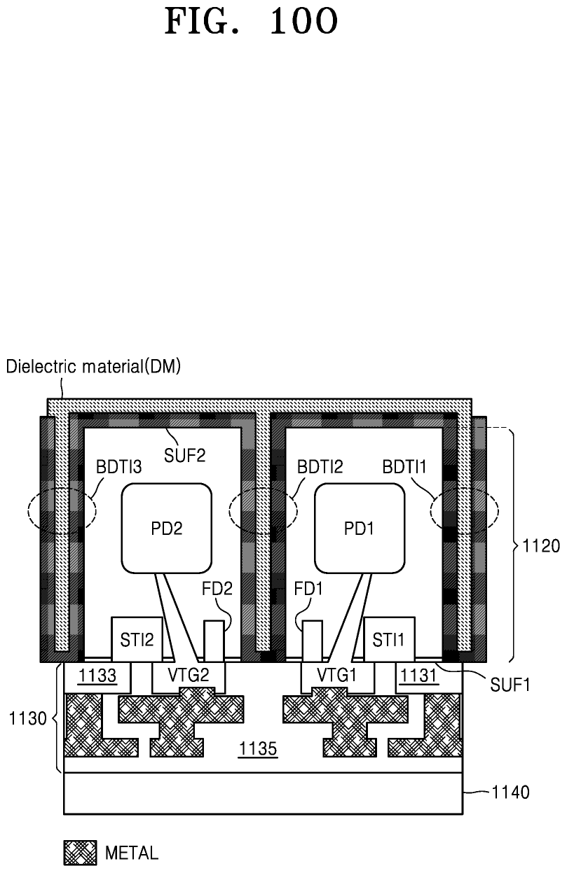

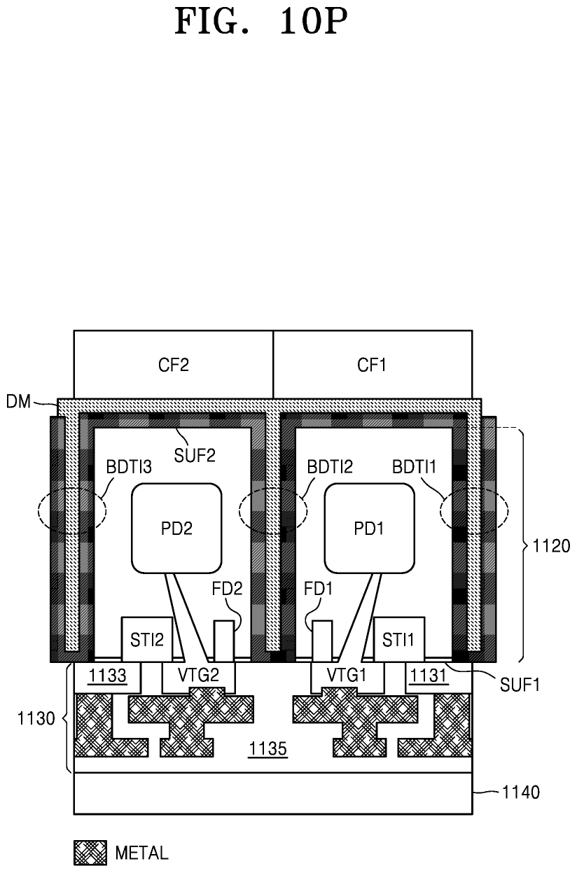

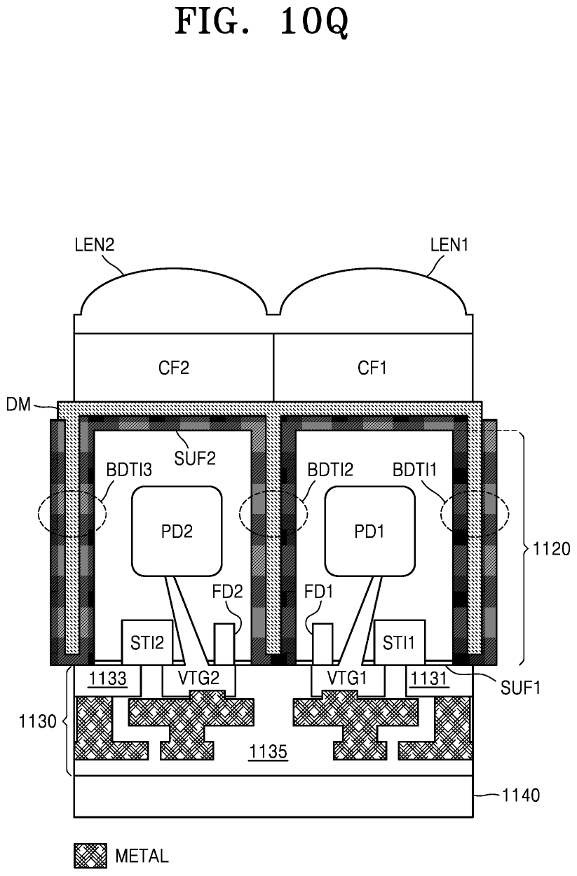

FIGS. 10A to 10Q are cross-sectional views illustrating a method of manufacturing pixels, according to an embodiment.

Referring to FIG. 10A, an epitaxial layer (e.g., a p epitaxial layer 1120) may be formed on a silicon substrate (e.g., a p+ silicon substrate 1110).

For example, the p epitaxial layer 1120 may be grown with the same crystal structure as that of a p+ silicon substrate using a silicon source gas. According to embodiments, each epitaxial layer may simply be referred to as a semiconductor substrate. For example, the silicon source gas may include silane, dichlorosilane (DCS), trichlorosilane (TCS), hexachlorodisilane (HCS), or a combination thereof. The p epitaxial layer 1120 may include a first surface (or upper region SUF1) and a second surface (or lower region SUF2).

Referring to FIG. 10B, a plurality of first isolation regions STI1 and STI2 may be formed in the p epitaxial layer 1120 by an etching process and/or a deposition process. For example, the plurality of first isolation regions STI1 and STI2 are trench-type isolation regions and may be STI regions. Hereinafter, the p epitaxial layer 1120 is interchangeably referred to as a semiconductor substrate.

Referring to FIG. 10C, the photoelectric conversion regions PD1 and PD2 may be formed between the first surface SUF1 and the second surface SUF2 by an ion implantation process. The photoelectric conversion regions PD1 and PD2 may generate charges based on incident light. For example, the photoelectric conversion regions PD1 and PD2 may generate charges in response to the incident light on the photoelectric conversion regions PD1 and PD2. A photodiode, phototransistor, photogate, or pinned photodiode may be formed in each of the photoelectric conversion regions PD1 and PD2. In an embodiment, the photoelectric conversion regions PD1 and PD2 may be photodiodes doped with impurities of the second conductivity type (e.g., n-type). In one example, the photoelectric conversion region 120 may be formed by stacking a plurality of regions having different impurity concentrations.

Referring to FIG. 10D, a mask pattern (Mask) for forming the first recess (recess1) may be formed on the first surface SUF1 of the semiconductor substrate 1120. Referring to FIG. 10E, in order to form a vertical transfer gate having an inclined structure, the semiconductor substrate 1120 may be inclined by a desired angle. For example, the semiconductor substrate 1120 may be rotated in a desired angle in a first direction (e.g., counter-clockwise direction).

Referring to FIG. 10F, etching may be performed while the semiconductor substrate 1120 is inclined to form the first recess (recess1). For example, the etching may be performed while the semiconductor substrate 1120 is rotated in the desired angle. In one embodiment, the semiconductor substrate 1120 that is inclined is anisotropically etched using the mask pattern (Mask) as an etch mask, so that the first recess (recess1) having an inclined angle may be formed. The first recess (recess1) may be formed through a wet etching process or a dry etching process. After a plurality of recesses are formed, an insulating layer may be formed to a predetermined thickness on the first surface SUF1.

Referring to FIG. 10G, a second recess (recess2) may be formed by repeating the process of FIGS. 10D to 10F. According to an embodiment, an angle at which the substrate is tilted may be different depending on a position of a maximum voltage point of each photoelectric conversion region. For example, the semiconductor substrate 1120 may be rotated in a desired angle in a second direction opposite to the first direction (e.g., clockwise direction), and etching may be performed while the semiconductor substrate 1120 is tilted to form the second recess (recess2). According to one example, the position of the maximum voltage point of each photoelectric conversion region may be determined through simulation.

According to an embodiment, the first recess (recess1) and the second recess (recess2) are etched in different steps and each recess is inclined while converging in the direction of the maximum voltage point. However, the disclosure is not limited thereto, and as such, according to another embodiment, the first recess (recess1) and the second recess (recess2) may be etched simultaneously. When the first recess (recess1) and the second recess (recess2) are simultaneously etched, the first recess (recess1) and the second recess (recess2) may be inclined toward the maximum voltage point in parallel with each other.

On the other hand, because the vertical transfer gate VTG extends into the first and second recesses (recess1) and (recess2) through a subsequent process, the width and depth of the recess may be determined based on a desired shape of the vertical transfer gate VTG. On the other hand, an example in which the first and second recesses (recess1) and (recess2) are formed in contact with the photoelectric conversion regions PD1 and PD2 is shown in the drawing of the inventive concept, but depending on embodiments, the first and second recesses (recess1) and (recess2) may be spaced apart from the photoelectric conversion regions PD1 and PD2 or extended to the inside of the photoelectric conversion regions PD1 and PD2.

Referring to FIG. 10H, each of the first and second transfer gate VTG1 and VTG2 may be formed on or above of a corresponding recess. For example, each transfer gate VTG1 and VTG2 may extend (or be formed) from the first surface SUF1 to each of the photoelectric conversion region PD1 and PD2. Each of the first and second transfer gates VTG1 and VTG2 may have an inclined structure with a slope based on the angle of the formed first and second recesses (recess1) and (recess2).

Each transfer gate VTG1 and VTG2 and other transfer gates 1131 and 1133 may be formed simultaneously. For example, other transfer gates 1131 and 1133 may include gates of reset transistors and gates of source followers.

For example, each of the first and second transfer gate VTG1 and VTG2, and other transfer gates 1131, and 1133 may be implemented as polysilicon, metal, or metal compound. As described above, an insulation layer (not shown) may be formed between each transfer gate VTG1, VTG2, 1131, and 1133 and the first surface SUF1.

Referring to FIG. 10I, each of first and second floating diffusion regions FD1 and FD2 may be formed at a certain depth from the first surface SUF1 of the P⁻ epitaxial layer 1120. According to embodiments, each of first and second floating diffusion regions FD1 and FD2 may be doped with N⁺ impurities.

Referring to FIG. 10J, a metal wiring region 1130 may be formed on (or above) the top surface of the p epitaxial layer 1120. The metal wiring region 1130 may include plurality of metals and plurality of contacts formed between a dielectric material 1135. The plurality of metals may be connected to each transfer gate VTG1, VTG2, 1131, and 1133 through the plurality of contacts. For example, the dielectric material 1135 may include an inter-layer dielectric or an inter level dielectric (ILD) or an intermetal dielectric (IMD).

Referring to FIG. 10K, a sustaining wafer 1140 may be bonded on the metal wiring region 1130. For example, a sustaining wafer 1140 may be used to sustain (or support) the p epitaxial layer 1120.

When FIG. 10K is turned over, it becomes FIG. 10L. Referring to FIG. 10M, the p+ silicon substrate 1110 is removed. According to embodiments, based on a mechanical method and/or a chemical method, the p+ silicon substrate 1110 may be ground.

Referring to FIG. 10N, to form the second isolation regions, for example, trench-type isolation regions BDTI1, BDTI2, and BDTI3, the corresponding regions are vertically etched on the second surface SUF2 of the p epitaxial layer 1120. Accordingly, trenches OP1, OP2, and OP3 corresponding to the trench-type isolation regions BDTI1, BDTI2, and BDTI3 may be formed.

Referring to FIG. 10O, empty spaces of the second surface SUF2 and the trenches OP1, OP2, and OP3 may be filled with a dielectric material DM. The trench-type isolation regions BDTI1, BDTI2, and BDTI3 may completely extend (or be formed) from the second surface SUF2 to the first surface SUF1. Each of the trench-type isolation regions BDTI1, BDTI2, and BDTI3 may mean a back deep trench isolation (DTI) region.

In FIG. 10O, an embodiment in which a DTI structure is formed by a DTI process for a back side is shown. However, the disclosure may not be limited thereto, and as such, according to another embodiment, the DTI may be frontside deep trench isolation (FDTI) region formed by a DTI process for the front side.

Referring to FIG. 10P, first and second color filters CF1 and CF2 may be formed on or above a dielectric material DM. The first color filter CF1 may be any one of a red color filter, a green color filter, and a blue color filter, and the second color filter CF2 may be another one of the red color filter, the green color filter, and the blue color filter.

Referring to FIG. 10Q, each of first and second microlenses LEN1 and LEN2 may be formed on or above each of the first and second color filters CF1 and CF2. The first photoelectric conversion region PD1 formed between the first surface SUF1 and the second surface SUF2 may generate charges based on incident light received through the first microlens LEN1, the first color filter CF1, and the second surface SUF2. In addition, the second photoelectric conversion region PD2 formed between the first surface SUF1 and the second surface SUF2 may generate charges based on incident light received through the second microlens LEN2, the second color filter CF2, and the second surface SUF2.

The corresponding two trench-type isolation regions BDTI1 and BDTI2 may surround the first photoelectric conversion region PD1 and may completely extend (or be formed) from the second surface SUF2 to the first surface SUF1. In addition, the two corresponding trench-type isolation regions BDTI2 and BDTI3 may surround the second photoelectric conversion region PD2 and completely extend (or be formed) from the second surface SUF2 to the first surface SUF1.

When viewed from the second surface SUF2 as a reference, each of first and second floating diffusion regions FD1 and FD2 may be formed below each photoelectric conversion region PD1 and PD2.

The first transfer gate VTG1 may extend (or be formed) vertically from the first surface SUF1 toward the first photoelectric conversion region PD1, and may transfer charges from the first photoelectric conversion region PD1 to the first floating diffusion region FD1 based on a corresponding voltage. In addition, the second transfer gate VTG2 may extend (or be formed) vertically from the first surface SUF1 toward the second photoelectric conversion region PD2, and may transfer charges from the second photoelectric conversion region PD2 to the second floating diffusion region FD2 based on a corresponding voltage. The first transfer gate VTG1 and the second transfer gate VTG2 may be provided in a structure inclined toward the maximum voltage point of the first photoelectric conversion region PD1 and the second photoelectric conversion region PD2 to improve charge transfer capability.

According to one or more example embodiments, the disclosure may describe that the second operation is performed after the first operation and the third operation is performed after the second operation. However, the disclosure is not limited thereto, and as such, according to another embodiment, the order of the first to third operations may be changed, and at least two of the first to third operations may be performed simultaneously. In addition, even if it is described that the second layer (or first device) is formed (or implemented) on or above the first layer (or second device), between the first layer and the second layer, one or more layers (or devices) may be formed (or implemented).

While the inventive concept has been particularly shown and described with reference to embodiments thereof, it will be understood that various changes in form and details may be made therein without departing from the spirit and scope of the following claims.

What is claimed is:

1. A pixel of an image sensor, the pixel comprising:
a semiconductor substrate comprising a first surface and a second surface;
a photoelectric conversion region between the first surface and the second surface of the semiconductor substrate;
a floating diffusion region on the first surface and spaced apart from the photoelectric conversion region in a vertical direction; and
a first vertical transfer gate in a first recess extending from the first surface of the semiconductor substrate to the photoelectric conversion region, the first vertical transfer gate configured to form a first transfer channel between the photoelectric conversion region and the floating diffusion region,
wherein the first vertical transfer gate has a structure inclined at a first angle of less than 90 degrees with respect to the first surface of the semiconductor substrate.

2. The pixel of claim 1, wherein the first vertical transfer gate is inclined in a direction in which a maximum voltage point of the photoelectric conversion region is located.

3. The pixel of claim 2, wherein the maximum voltage point of the photoelectric conversion region is a point in the photoelectric conversion region having a greatest doping concentration of impurities of a first conductivity type.

4. The pixel of claim 3, wherein the semiconductor substrate is doped with impurities of a second conductivity type.

5. The pixel of claim 2, wherein the first vertical transfer gate contacts the photoelectric conversion region.

6. The pixel of claim 2, further comprising:
a second vertical transfer gate spaced apart from the first vertical transfer gate,
wherein second vertical transfer gate is in a second recess extending from the first surface of the semiconductor substrate to the photoelectric conversion region, the second vertical transfer gate configured to form a second transfer channel between the photoelectric conversion region and the floating diffusion region.

7. The pixel of claim 6, wherein the second vertical transfer gate has a structure inclined at a second angle less than 90 degrees with respect to the first surface.

8. The pixel of claim 7, wherein the first angle is same as the second angle.

9. A pixel of an image sensor, the pixel comprising:
a semiconductor substrate comprising a first surface and a second surface;
a photoelectric conversion region between the first surface and the second surface of the semiconductor substrate;
a floating diffusion region provided in a cylindrical shape extending from the first surface of the semiconductor substrate into the semiconductor substrate; and
a vertical transfer gate provided in a cylindrical shape surrounding the floating diffusion region and extending from the first surface of the semiconductor substrate to the photoelectric conversion region, the vertical transfer gate configured to form a transfer channel between the photoelectric conversion region and the floating diffusion region,
wherein the vertical transfer gate and the floating diffusion region have a structure inclined at an angle less than 90 degrees with the first surface.

10. The pixel of claim 9, wherein the vertical transfer gate is inclined in a direction in which a maximum voltage point of the photoelectric conversion region is located.

11. The pixel of claim 10, wherein the maximum voltage point of the photoelectric conversion region is a point in the photoelectric conversion region having a greatest doping concentration of impurities of a first conductivity type.

12. The pixel of claim 11, wherein the semiconductor substrate is doped with impurities of a second conductivity type.

13. A backside illuminated (BSI) image sensor comprising:
a pixel array comprises a plurality of pixels configured to generate a plurality of pixel signals based on incident light; and a signal unit configured to output image data based on the plurality of pixel signals,
wherein at least one of the plurality of pixels comprises:
a semiconductor substrate comprising a first surface and a second surface;
a photoelectric conversion region between the first surface and the second surface;
a floating diffusion region on the first surface of the semiconductor substrate and spaced apart from the photoelectric conversion region in a vertical direction; and
a first vertical transfer gate in a first recess extending from the first surface of the semiconductor substrate to the photoelectric conversion region, the first vertical transfer gate configured to form a first transfer channel between the photoelectric conversion region and the floating diffusion region,
wherein the first vertical transfer gate has a structure inclined toward a maximum voltage point of the photoelectric conversion region.

14. The BSI image sensor of claim 13, wherein the maximum voltage point of the photoelectric conversion region is a point in the photoelectric conversion region having a greatest doping concentration of impurities of a first conductivity type.

15. The BSI image sensor of claim 14, wherein the semiconductor substrate is doped with impurities of a second conductivity type.

16. The BSI image sensor of claim 13, wherein the first vertical transfer gate contacts the photoelectric conversion region.

17. The BSI image sensor of claim 13, further comprising:
a second vertical transfer gate spaced apart from the first vertical transfer gate,
wherein second vertical transfer gate is in a second recess extending from the first surface of the semiconductor substrate to the photoelectric conversion region, the second vertical transfer gate configured to form a second transfer channel between the photoelectric conversion region and the floating diffusion region.

18. The BSI image sensor of claim 17, wherein the second vertical transfer gate has a structure inclined toward the maximum voltage point.

19. The BSI image sensor of claim 18, wherein the first vertical transfer gate and the second vertical transfer gate are provided symmetrical to each other with respect to the maximum voltage point.

20. The BSI image sensor of claim 19, wherein an inclination angle of the first vertical transfer gate is equal to an inclination angle of the second vertical transfer gate.
